(19) United States
(12) Patent Application Publication
(10) Pub. No.: US 2011/0082053 A1
(43) Pub. Date: Apr. 7, 2011

(54) Molecular Rectifiers Comprising Diamondoids

(76) Inventors: Wanli Yang, El Cerrito, CA (US); Zhi-Xun Shen, Stanford, CA (US); Harindran C. Manoharan, Los Gatos, CA (US); Nicholas A. Melosh, Menlo Park, CA (US); Michael A. Kelly, Portola Valley, CA (US); Andrey A. Fokin, Giessen (DE); Peter R. Schreiner, Wettenberg (DE); Jason C. Randel, San Francisco, CA (US)

(21) Appl. No.: 12/865,391

(22) PCT Filed: Jan. 30, 2009
(86) PCT No.: PCT/US09/00619

§ 371 Date: Dec. 17, 2010

Related U.S. Application Data
(60) Provisional application No. 61/006,801, filed on Jan. 31, 2008.

(51) Int. Cl. C40B 40/04; C07C 255/47; C07C 61/12; C07C 251/18; C07C 211/38; C07C 321/22; C07C 35/22; C07C 205/05; C07C 23/18; C07C 13/615; B82Y 99/00

(52) U.S. Cl. 506/15; 558/429; 562/498; 564/270; 564/458; 568/77; 568/817; 568/818; 568/941; 570/130; 570/187; 585/22; 977/734; 977/742

(57) ABSTRACT

Provided is a molecular rectifier comprised of a diamondoid molecule and an electron acceptor attached to the diamondoid molecule. The electron acceptor is generally an electron accepting aromatic species which is covalently attached to the diamondoid.

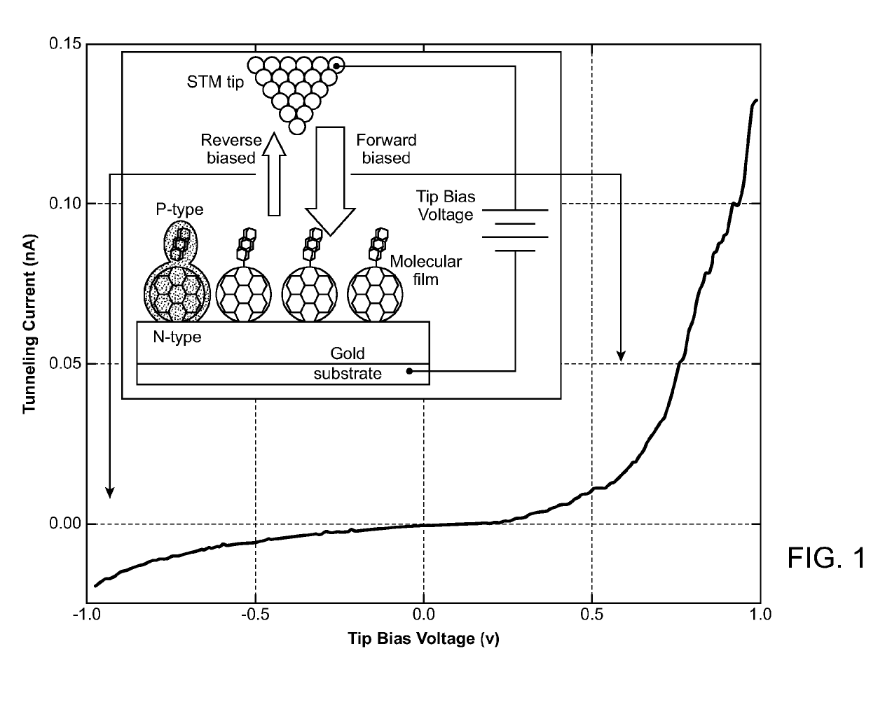

### BACKGROUND

Electronic rectifiers restrict current flow in certain directions, and are essential components in electronic devices. Rectification occurs when electrons transfer more favorably in one direction than another. This may occur in a number of physical structures, such as p-n junctions, charge transfer complexes, or Schottky diodes. Rectification is critical for electronic memory and crossbar structures to limit stray currents. With the push for smaller electronic devices, nanoscale rectifiers have become more important. The ultimate limit is a molecular rectifier, formed by a single molecule or molecular layer which could be sandwiched between two electrodes. Requirements for rectifiers include high on-off ratio, thermal as well as electrical stability, and consistent turn-on voltage. These electronic properties have engendered applications ranging from diodes, memory elements, basic transistors, light-emitting diodes, solar cells and photodetectors.

As nanotechnology becomes a more important consideration in today's electronic industry, forming electronic devices on the molecular level becomes more important. The ability to form a rectifier or p-n junction at the molecular level, for example, would have wide appeal in the industry, and further the applicability of nanotechnology in today's world. The industry, therefore, is always looking for the means to generate electronic devices on a smaller scale, and hopefully at the nano scale.

### SUMMARY

Provided is a molecular rectifier comprised of a diamondoid molecule and an electron acceptor attached to the diamondoid molecule. The electron acceptor is generally an electron accepting aromatic species which is covalently attached to the diamondoid. Depending upon the particular diamondoid, these molecules may act as rectifiers, resistors, p-n junctions, or a combination thereof.

Among other factors, it has been discovered that by utilizing a diamondoid, one can achieve rectification at the molecular level. The diamondoid molecule fulfills the role of an electron donor, and by combining the diamondoid molecule with an electron acceptor, and most notably an aromatic electron acceptor, rectification at the molecular level can be achieved. The chemistry in preparing the molecules is flexible, allowing tuning of the specific behavior. The use of diamondoids permits the realization of a practical rectifying junction at the molecular level, and its application in diodes, basic transistors, light-emitting diodes, and other electronic devices.

### BRIEF DESCRIPTION OF THE FIGURE

The FIGURE graphically depicts the tunneling current observed for a p-n junction comprised of a diamondoid molecule.

### DETAILED DESCRIPTION

The ultimate limit in size reduction for a rectifying junction would be a single molecule with one section electron donating and another section electron accepting. Diamondoids are one example of an electron donor molecular material that has excellent electronic properties. Diamond itself has one of the highest hole mobilities measured. Diamondoids are also believed to have exceptional properties. Diamondoids have proven to be effective electron emitters as they display a negative electron affinity. By combining diamondoids with an electron acceptor material, a molecular rectifier or p-n junction may be formed. Here we refer to “N-type” materials as anything that can serve as an electron acceptor (or electron-withdrawing group) when in contact with the diamondoid, such materials include but are not limited to C₆₀, carbon nanotubes, or conducting polymers; it also includes molecular functionalization on the diamondoid itself such as —NO₂, —CN, halogens (F, Cl, Br, I), alkenes, etc. We then refer to electron donors, such as diamondoids, as “p-type”, though these designations may not hold the same physical meaning as in semiconductor materials. A molecular rectifier may thus be described as a p-n junction, though this does not imply the physics of the junction is identical as in typical semiconductor p-n junctions as these are in fact molecular materials. In conjunction with electron acceptors, the combination with diamondoids leads to rectifying devices such as organic diodes. Some C₆₀-diamondoid junctions have been shown to act as rectifiers.

The term “diamondoids” refers to substituted and unsubstituted cage compounds of the adamantane series including adamantane, diamantane, triamantane, tetramantanes, pentamantanes, hexamantanes, heptamantanes, octamantanes, nonamantanes, decamantanes, undecamantanes, and the like, including all isomers and stereoisomers thereof. The compounds have a “diamondoid” topology, which means their carbon atom arrangement is superimposable on a fragment of a FCC diamond lattice. Substituted diamondoids typically comprise from 1 to 10, and more preferably from 1 to 4 independently-selected alkyl substituents. Diamondoids include “lower diamondoids” and “higher diamondoids,” as these terms are defined herein, as well as mixtures of any combination of lower and higher diamondoids.

The term “lower diamondoids” refers to adamantane, diamantane and triamantane and any and/or all unsubstituted and substituted derivatives of adamantane, diamantane and triamantane. These lower diamondoid components show no isomers or chirality and are readily synthesized, distinguishing them from “higher diamondoids.”

The term “higher diamondoids” refers to any and/or all substituted and unsubstituted tetramantane components; to any and/or all substituted and unsubstituted pentamantane components; to any and/or all substituted and unsubstituted hexamantane components; to any and/or all substituted and unsubstituted heptamantane components; to any and/or all substituted and unsubstituted nonamantane components; to any and/or all substituted and unsubstituted decamantane components; to any and or all substituted and undecamantane components; as well as mixtures of the above and isomers and stereoisomers of tetramantane, pentamantane, hexamantane, heptamantane, octamantane, nonamantane, decamantane, and undecamantane.

Adamantane chemistry has been reviewed by Fort, Jr. et al. in “Adamantane: Consequences of the Diamondoid Structure,” Chem. Rev. vol. 64, pp. 277-300 (1964). Adamantane is the smallest member of the diamondoid series and may be thought of as a single cage crystalline subunit. Diamantane contains two subunits, triamantane three, tetramantane four, and so on. While there is only one isomeric form of adamantane, diamantane, and triamantane, there are four different isomers of tetramantane, (two of which represent an enantiomeric pair), i.e., four different possible ways or arranging the four adamantane subunits. The number of possible isomers increases non-linearly with each higher member of the diamondoid series, pentamantane, hexamantane, heptamantane, octamantane, nonamantane, decamantane, etc.

Adamantane, which is commercially available, has been studied extensively. The studies have been directed toward a number of areas, such as thermodynamic stability, functionalization, and the properties of adamantane-containing materials. For instance, the following patents discuss materials comprising adamantane subunits: U.S. Pat. No. 3,457,318 teaches the preparation of polymers from alkenyl adamantanes; U.S. Pat. No. 3,832,332 teaches a polyamide polymer forms from alkyladamantane diamine; U.S. Pat. No. 5,017,734 discusses the formation of thermally stable resins from adamantane derivatives; and U.S. Pat. No. 6,325,851 reports the synthesis and polymerization of a variety of adamantane derivatives.

The four tetramantane structures are iso-tetramantane [1(2)3], anti-tetramantane [121], and two enantiomers of skew-tetramantane [123], with the bracketed nomenclature for these diamondoids in accordance with a convention established by Balaban et al. in “Systematic Classification and Nomenclature of Diamond Hydrocarbons-I,” Tetrahedron vol. 34, pp. 3599-3606 (1978). All four tetramantanes have the formula C₂₂H₂₈ (molecular weight 292). There are ten possible pentamantanes nine having the molecular formula C₂₆H₃₂ (molecular weight 344) and among these nine there are three pairs of enantiomers represented generally by [12(1)3)], [1234], [1213] with the nine enantiomeric pentamantanes represented by [12(3)4], [1212]. There also exists a pentamantane [1231] represented by the molecular formula C₂₅H₃₀ (molecular weight 330).

Hexamantanes exist in thirty-nine possible structures with twenty eight having the molecular formula C₃₀H₃₆ (molecular weight 396) and of these, six are symmetrical; ten hexamantanes have the molecular formula C₂₉H₃₄ (molecular weight 382) and the remaining hexamantane [12312] has the molecular formula C₂₆H₃₀ (molecular weight 342).

Heptamantanes are postulated to exist in 160 possible structures with 85 having the molecular formula C₃₄H₄₀ (molecular weight 448) and of these, seven are achiral, having no enantiomers. Of the remaining heptamantanes, 67 have the molecular formula C₃₃H₃₈ (molecular weight 434), six have the molecular formula C₃₂H₃₆ (molecular weight 420) and the remaining two have the molecular formula C₃₀H₃₄ (molecular weight 394).

Octamantanes possess eight of the adamantane subunits and exist with five different molecular weights. Among the octamantanes, 18 have the molecular formula C₄₃H₃₈ (molecular weight 446). Octamantanes also have the molecular formula C₃₈H₄₄ (molecular weight 500); C₃₇H₄₂ (molecular weight 486); C₃₆H₄₀ (molecular weight 472), and C₃₃H₃₆ (molecular weight 432).

Nonamantanes exist within six families of different molecular weights having the following molecular formulas; C₄₂H₄₈ (molecular weight 552), C₄₁H₄₆ (molecular weight 538), C₄₀H₄₄ (molecular weight 524), C₃₈H₄₂ (molecular weight 498), C₃₇H₄₀ (molecular weight 484) and C₃₄H₃₆ (molecular weight 444).

Decamantane exists within families of seven different molecular weights. Among the decamantanes, there is a single decamantane having the molecular formula C₃₅H₃₆ (molecular weight 456) which is structurally compact in relation to the other decamantanes. The other decamantane families have the molecular formulas: C₄₆H₆₂ (molecular weight 604); C₄₅H₅₀ (molecular weight 590); C₄₄H₄₈ (molecular weight 576); C₄₂H₄₆ (molecular weight 550); C₄₁H₄₄ (molecular weight 536); and C₃₈H₄₀ (molecular weight 496).

Undecamantane exists within families of eight different molecular weights. Among the undecamantanes there are two undecamantanes having the molecular formula C₃₉H₄₀ (molecular weight 508) which are structurally compact in relation to the undecamantanes. The other undecamantane families have the molecular formulas C₄₁H₄₂ (molecular weight 534); C₄₂H₄₄ (molecular weight 548); C₄₅H₄₈ (molecular weight 588); C₄₆H₅₀ (molecular weight 602); C₄₈H₅₂ (molecular weight 628); C₄₉H₆₄ (molecular weight 642); and C₅₀H₅₆ (molecular weight 656).

Methods of forming diamondoid derivatives, heterodiamondoids, and polymerizing diamondoids, are discussed, for example, in U.S. Pat. No. 7,049,344; U.S. Patent Publication 2003/0193710; and U.S. Patent Publication 2002/0177743; which are all incorporated herein by reference in their entirety to an extent not inconsisting herewith.

The diamondoid p-n or rectifier junction may be created by chemical functionalization of the diamondoid, or by simple physical contact, for instance by depositing an n-type conductive layer on top of the diamondoid. Generally, however, the molecule p-n junction comprises a diamondoid molecule and a molecular or chemical functionality covalently attached to the diamondoid molecule. The chemical functionality covalently attached generally functions as an electron acceptor.

In one embodiment, the diamondoid molecule is selected from the group of higher diamondoids, lower diamondoids, functionalized diamondoids and heterodiamondoids. In another embodiment the diamondoid molecule is adamantane, diamantane, triamantane or tetramantane. When a functionalized molecule is used, in one embodiment the diamondoid is functionalized with an —SH, —OH, —COOH, —NH₂, vinyl, butadienyl, or alkynyl group, or other similar functional moieties. These groups, particularly the third functionality, provide for a well defined attachment point for the diamondoid itself to guarantee proper orientation for a rectifier or p-n junction operation.

The molecule or chemical functionality which generally functions as an electron acceptor is generally an electron accepting aromatic species, such as, but not limited to a conducting polymer, —NO₂, —CN, halogens, i.e., F, Cl, Br, and I, alkenes, alkynes and the like. In another embodiment, the electron acceptor covalently attached is a fullerene, carbon nanotube or functionalized variations thereof; as well as polyacenes, graphenes, polyaromatics, polyheteroaromatics and substituted variations thereof. In one embodiment, the fullerene is preferably a Cₛₒ molecule.

In connecting the electron acceptor to the diamondoid, a number of connecting groups can be used. Among those suitable connecting groups are a cyclohexene connector, an azomethine connector, a cyclopropane connector, (e.g. Bingel coupling) and the like, as well as variations/combinations thereof.

The method generally used in making the molecule p-n junction involves first chemically modifying a diamondoid derivative with a diene functionality. The modified diamondoid is then reacted with an electron acceptor to yield a molecular rectifier junction as a Diels-Alder adduct. The diene functionality used determines the particular connecting group that results. In some embodiments, the electron acceptor aromatic species is a fullerene molecule, and specifically a C₆₀.

Many different applications are possible for the molecular rectifier or p-n junction. One application may be for splitting excitons within solar cells, though any application where conventional rectifier or p-n-junctions are used may also benefit from the present junctions comprising diamondoids.

Another important application is for light emitting diodes (LEDs). In an LED, holes and electrons are injected into the p- and n-type materials, respectively. They recombine within the depletion region, emitting light equal to the difference in energy between the two carriers in the material's. The specific emission wavelength can be tuned by adding functional groups to the p- and n-type molecular units to increase or decrease the energy between the two. This allows rational design of multicolor LED elements based upon the same starting material, which will reduce the difficulty of integrating different materials into one device element.

These devices can be made by orienting a monolayer of the diamondoid-electron acceptor conjugate on an electrode such that the molecules are pointing the same way, or by random mixtures of the molecule. In this case the two components locally phase separate giving p- or n-type percolation paths through the material. Unlike conventional LED's based on opaque semiconductors, the ultra-thin and relatively transparent diamondoids would allow light to pass through the device itself. This allows large-area illumination, similar to organic LEDs (OLEDs), which is ideal for illumination or display technologies.

Organic molecular diodes incorporating diamondoids have been prepared in adducts of butadienyl-substituted adamantane, diamantane, and tetramantane with Buckminsterfullerene C₆₀ via Diels-Alder reaction (Scheme 1, below). Double addition results in a dumbell-shaped structure that formally presents a n-p-n-type junction, i.e., an organic, molecular transistor.

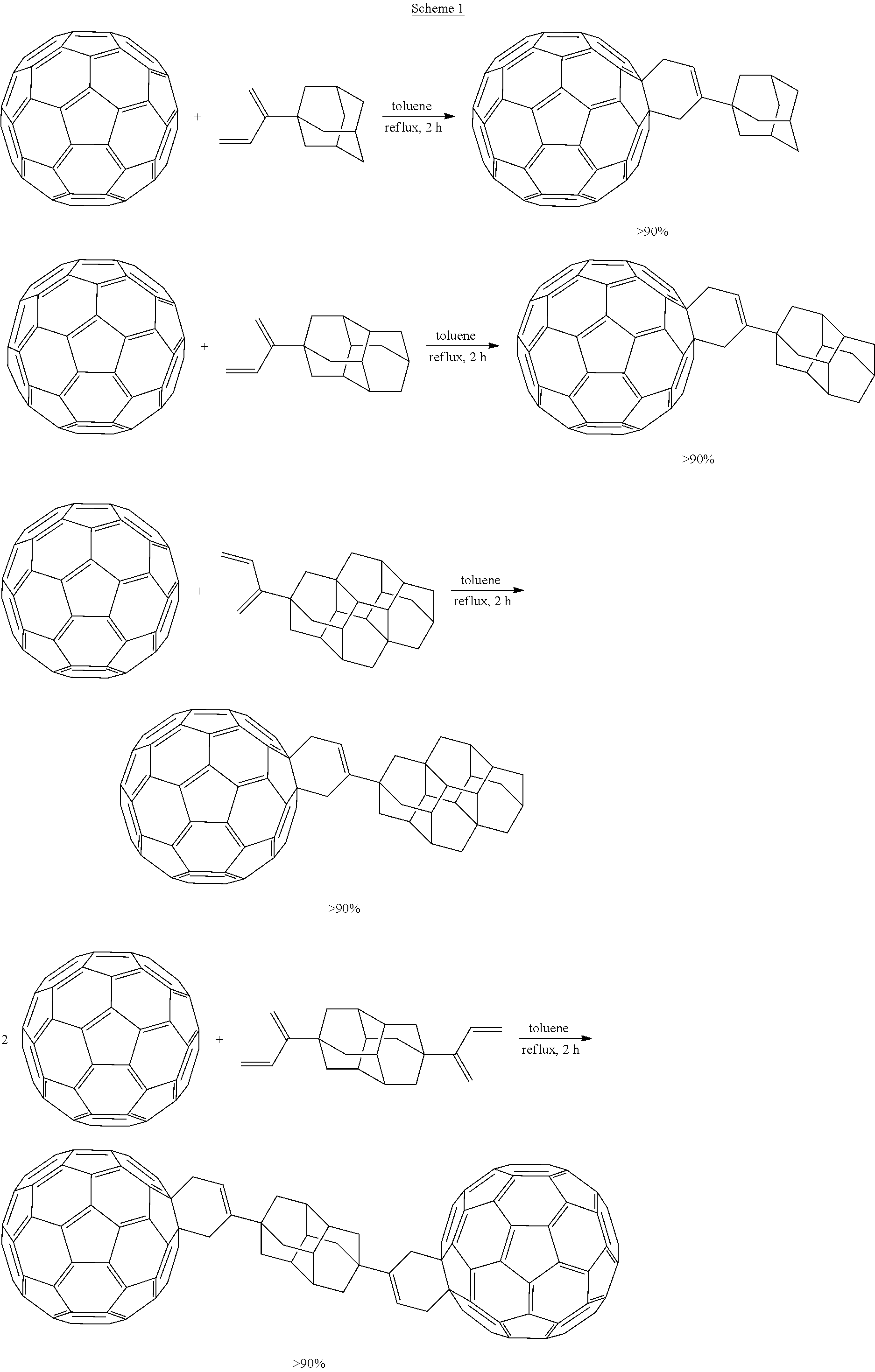

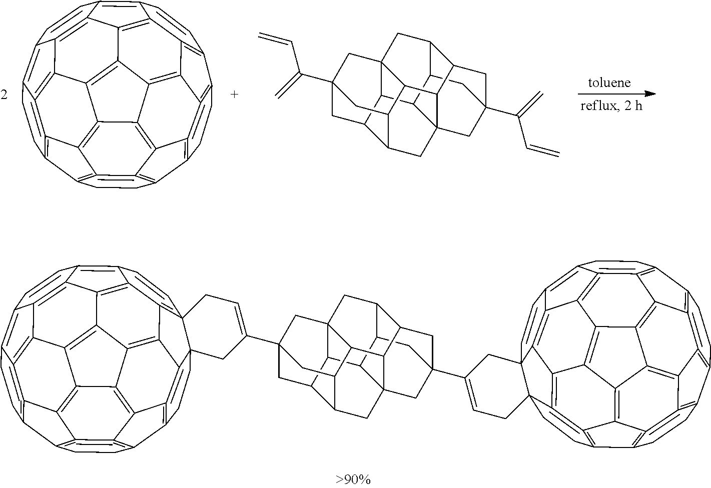

Initial measurements strongly suggest that indeed the current is direction dependent, i.e., diode-like as shown in the FIGURE. With this proof-of-principle at hand and as will be appreciated by those of skill in the art, a large number of such molecular p-n-junction materials are possible. With an eye on synthetic feasibility, as noted above, generally any electron acceptor can be connected with a diamondoid to operate as a rectifier or p-n-junction. When using a fullerene as the electron acceptor, the attachment points for the organic diodes are either on the side of the fullerene (potentially complicated because of many stereoisomers) or on the side of the diamondoid (much more feasible). Accordingly, in some embodiments, substitution of the diamondoid with functional groups such as —SH, —OH, —COOH, —NH₂, vinyl, butadienyl or alkynyl groups are therefore preferred.

In another embodiment, any aromatic electron-acceptor will be useful for molecular p-n junctions (Scheme 2, below). This includes polyacenes, graphenes, polyaromatics, polyhetereoaromatics, substituted polyheteroaromatics and the like.

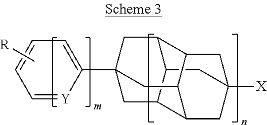

The connection of the diamondoid to aromatics can be made readily through bromination of the diamondoid and Friedel-Crafts alkylation. Alternative synthetic approaches include Pd-catalyzed coupling. An important aspect is to utilize aromatics that are good electron acceptors (e.g., R═CN or NO₂). The large variation in aromatic substituent can be exploited in tuning the specific behavior.

As a specific example, in one embodiment a cyclohexene derivative can be used as the connector for the sake of using a thermal [4+2] Diels-Alder reaction utilizing the underivatized fullerene and a 2-diamondoidyl substituted 1,3-butadiene (for available dienes and their synthesis see Scheme 3, below). As the reaction is thermally reversible, other connectors can be used.

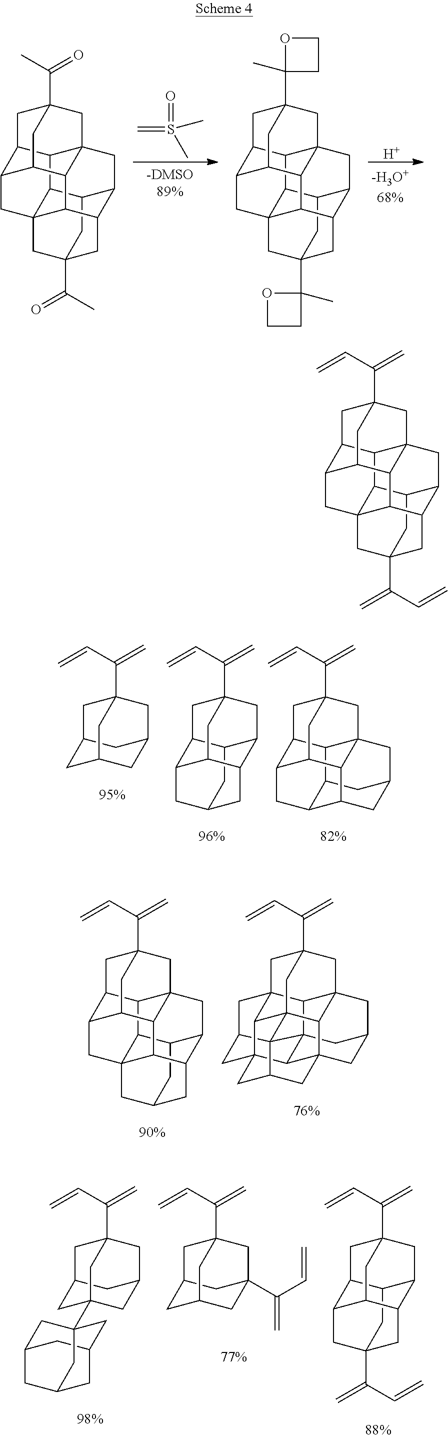

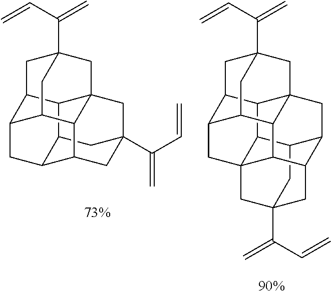

Alternatives include primarily azomethine and cyclopropane (via Bingel reactions) attachments (Scheme 4).

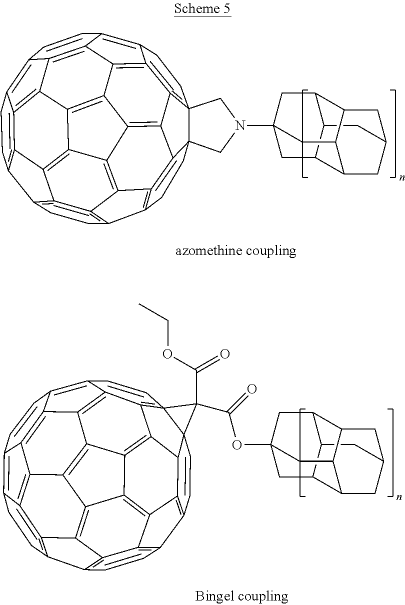

As depicted in Scheme 2, above, it is important to provide well-defined attachment points for the diamondoids themselves (denoted as —X) to guarantee proper orientation for rectifier or p-n-junction operation. Currently, thiol functionalities for -x=SH for attachment on gold or silver seem to be the most promising. However, other attachment points (also to alternative surfaces) can be considered e.g., —X=OH, COOH, NH₂, vinyl, butadienyl, alkynyl and the like.

Many modifications of the exemplary embodiments of the subject matter disclosed above will readily occur to those skilled in the art. Accordingly, the invention is to be construed as including all embodiments that fall within the scope of the appended claims.

1. A molecule exhibiting rectifying properties comprising: a) a diamondoid molecule; and b) a molecular or chemical functionality covalently attached to said diamondoid molecule, wherein the combination functions to conduct current preferentially in one direction.

2. The molecule of claim 1, wherein the combination of the diamondoid molecule and molecular or chemical functionality covalently attached thereto function as a p-n function.

3. The molecule of claim 1, wherein the diamondoid molecule is selected from the group consisting of higher diamondoids, lower diamondoids, functionalized diamondoids, and heterodiamondoids.

4. The molecule of claim 1, wherein the molecular or chemical functionality is selected from the group consisting of fullerenes, carbon nanotubes, and functionalized variations thereof.

5. The molecule of claim 1, wherein the molecular or chemical functionality is selected from the group consisting of conducting polymers, electron deficient aromatic species, —NO₂, —CN, halogens (F, Cl, Br, and I), and alkenes.

6. The molecule of claim 4, wherein the molecular or chemical functionality is C₆₀.

7. The molecule of claim 1, wherein the molecular or chemical functionality is selected from the group consisting of polyacenes, graphenes, polyaromatics, polyheteroaromatics, and substituted variations thereof.

8. The molecule of claim 1, wherein the molecular or chemical functionality is an aromatic species substituted with a —CN group.

9. The molecule of claim 1, wherein the diamondoid molecule is functionalized with a —SH, —OH, —COOH₁—NH₂, vinyl, butadienyl or alkynyl group.

10. The molecule of claim 1, wherein the molecular or chemical functionality covalent attached to said diamondoid molecule is attached through a connector selected from the group consisting of a cyclohexene connector, an azomethine connector and a cyclopropane connector.

11. The molecule of claim 10, wherein the connector is a cyclohexene connector.

12. A method for making a molecular rectifier or p-n junction, said method comprising the steps of: a) chemically-modifying a diamondoid molecule to yield a diamondoid derivative comprising a diene functionality; and b) reacting the diamondoid with an electron-acceptor aromatic species to yield a molecular rectifier or p-n junction as a Diels-Alder adduct.

13. The method of claim 12, wherein the diamondoid molecule is selected from the group consisting of higher diamondoids, lower diamondoids, functionalized diamondoids, and heterodiamondoids.

14. The method of claim 12, wherein the electron-acceptor aromatic species is a fullerene.

15. The method of claim 14, wherein the fullerene is C₆₀.

16. The method of claim 12, wherein the electron-acceptor aromatic species is substituted with a —CN group.

17. An array comprising a plurality of the rectifying molecules of claim 1.

18. The array of claim 17, wherein the molecular junctions within the array are chemically-anchored to a substrate.

19. The array of claim 18, wherein the substrate is comprised of gold or silver.

20. A photoluminescent device comprising a plurality of the rectifying molecules of claim 1.

21. The photoluminescent device of claim 20, wherein said device generally functions as a light-emitting diode.

22. A photovoltaic device comprising a plurality of the rectifying molecules of claim 1.

23. The photovoltaic device of claim 22, wherein said device generally functions as a solar cell.

24. A transistor which comprises at least one of the rectifying molecules of claim 1.

25. A transistor which comprises at least one of the molecules of claim 2.

26. The transistor of claim 25, wherein the molecule is a dumbbell-shaped structure that represents a n-p-n type junction.
